(19) United States
(12) Patent Application Publication
(10) Pub. No.: US 2026/0188972 A1
(43) Pub. Date: Jul. 2, 2026

(54) SCALABLE SURFACE-EMITTING LASERS WITH A UNIFORM FUNDAMENTAL MODE

(71) Applicant: Topolight, Inc., Berkeley, CA (US)

(72) Inventors: Rushin Contractor, Berkeley, CA (US); Daniel Klawson, Berkeley, CA (US)

(21) Appl. No.: 19/394,767

(22) Filed: Nov. 19, 2025

Related U.S. Application Data
(60) Provisional application No. 63/738,988, filed on Dec. 26, 2024.

(51) Int. Cl. H01S 5/10; H01S 5/024; H01S 5/11; H01S 5/42

(52) U.S. Cl. CPC H01S 5/1021; H01S 5/02469; H01S 5/11; H01S 5/423

(57) ABSTRACT

A VCSEL-pumped uniform-field cavity (VPUFC) includes a substrate, one or more vertical cavity surface emitting lasers (VCSEL) bonded to the substrate and a heat sink wafer disposed proximate an emitting surface of the VCSEL. The one or more VCSEL is disposed between the substrate and the heat sink wafer. A uniform field cavity (UFC) is optically coupled to the VCSEL(s) through the heat sink wafer, which is disposed between the VCSEL(s) and UFC. The one or more VCSEL is configured to optically pump the UFC.

### CLAIM OF PRIORITY

This application claims the priority benefit of U.S. Provisional Patent Application No. 63/738,988 filed Dec. 26, 2025, the entire disclosures of which are incorporated herein by reference.

### FIELD OF THE DISCLSOURE

The present disclosure relates to vertical cavity surface-emitting lasers (VCSELs) and more specifically to VCSEL-pumped uniform-field cavities (VPUFCs).

### BACKGROUND

Semiconductor lasers are rapidly approaching their limits in terms of scalability. Increasing the power output often leads to multimode operation, which compromises beam quality and limits their effectiveness in high-power applications.

It is within this context that aspects of the present disclosure arise.

### INTRODUCTION

It is desirable to develop a new class of scalable semiconductor lasers that overcome the above-described scalability limitations by utilizing novel cavities that support a uniform field distribution. Such a design enables lasers to maintain single-mode operation regardless of cavity size or power output, significantly extending the range of applications for semiconductor lasers beyond their conventional low-power, commercial uses. Aspects of the present disclosure leverage a novel design framework based on photonic crystal surface-emitting lasers (PCSELs), which enables high-intensity, coherent light emission while maintaining single-mode operation over a wide range of powers and cavity sizes. The core innovation in our approach lies in the design of the laser cavity, which features a uniform field distribution. This uniform field allows us to scale the cavity size without degrading beam quality or introducing unwanted multimode operation. The uniform-field cavity (UFC) design also improves heat dissipation, as the power density remains evenly distributed across the laser aperture, preventing the formation of localized hotspots and reducing the need for active cooling mechanisms. Conventional PCSELs require complex manufacturing processes that are not suitable for 2-micron or longer wavelengths—our streamlined manufacturing process does not require multiple stages of epitaxial regrowth or electron beam lithography. This unlocks easy, large-scale fabrication of our lasers.

To mitigate the difficulty in injecting current over a wide area, we will co-package the cavities with a VCSEL-array pump. As a result, our VCSEL-pumped uniform-field cavities (VPUFC) lasers can be operated electrically. We will manufacture photonic crystal cavities spanning 3 mm bonded with a thermally conductive heat sink. These cavities will be packaged with a VCSEL-array capable of delivering 3 Watts of multimode power. The photonic crystal UFC will convert the low coherence light emitted from the VCSELs into a single, narrow divergence beam with a flat mode profile and a Gaussian far field—this enables efficient fiber coupling with minimal external optics. This modular and adaptable design is for low size, weight, and power (low-SWaP) applications.

In summary, an innovative semiconductor laser design according to aspects of the present disclosure represents a significant leap forward in laser technology by overcoming the traditional limitations of multimode operation and poor scalability. Our uniform-field cavity design not only enhances beam quality and power output but also offers the flexibility needed to address a wide variety of high-performance applications across defense, aerospace, medical, industrial, and communications sectors.

### POTENTIAL BENEFITS AND COMMERCIAL APPLICATIONS

VCSEL-pumped uniform-field cavity (VPUFC) technology according to aspects of the present disclosure has the potential to transform multiple industries by providing high-power single-mode lasers with compact, scalable, and cost-effective designs. Although initially targeting 2 μm wavelength for defense and ISR applications, wavelength-flexible VPUFC technology may address broader applications across industrial, medical, and telecommunications markets, where cost, precision, and low size, weight, and power (SWaP) are crucial.

VPUFC lasers offer high power, low-divergence single-mode beams making them ideal for high-performance applications. Streamlined, single-step epitaxial growth and all-optical lithography process support high-throughput manufacturing, drastically reducing production costs compared to conventional high power laser technologies like solid-state and gas devices. These qualities position VPUFCs as a practical, low-cost alternative for sectors requiring precise, compact laser solutions.

Besides defense and ISR, one of the most promising initial target markets is the semiconductor manufacturing industry, a sector which has seen a meteoric rise in demand over the past few years. VPUFCs represent a cost-effective solution for laser dicing—sub 10 μm sized, Watt level beams cut through silicon substrates to extract the valuable microelectronic chips. Current laser systems can exceed $800,000 per unit (replaced every 2000 hours), representing a massive cost only affordable by high-volume commercial foundries. Because of the low cost of our technology, we envision new modes of operation like parallel wafer dicing, significantly increasing throughput and lowering operational costs. The laser materials processing market is projected to reach $10 billion by 2030, driven by growth in precision cutting and welding applications, while the global military laser market is expected to grow from $5 billion in 2023 to nearly $8 billion by 2030.

### GLOSSARY

TRL: Technology readiness level
LIDAR: Light detection and ranging
VCSEL: Vertical-cavity surface-emitting laser
PCSEL: Photonic crystal surface-emitting laser
RIE: Reactive ion etching
ICP: Inductively coupled plasma
UFC: Uniform field cavity
VPUFC: VCSEL-pumped UFC

### SUMMARY

Aspects of the present disclosure include VCSEL-pumped uniform-field cavity (VPUFC), having a substrate, one or more vertical cavity surface emitting laser (VCSEL), a heat sink, and a uniform field cavity (UFC). The one or more vertical cavity surface emitting laser (VCSEL) are bonded to the substrate. The heat sink wafer is disposed proximate an emitting surface of the VCSEL so that the one or more VCSEL is disposed between the substrate and the heat sink wafer. The UFC is optically coupled to the one or more VCSEL through the heat sink wafer, which is disposed between the one or more VCSEL and the UFC. The one or more VCSEL is configured to optically pump the UFC.

In some implementations, the UFC may be configured to support a fundamental mode of radiation. In some such implementations, the uniform field cavity may include photonic crystal cavity. The photonic crystal may have a six-fold symmetry and may be truncated as a hexagon, rhombus, or any arbitrary cavity shape with the cavity edges parallel to the lattice vectors.. The photonic crystal may have a rhombic shape. Generally speaking, the photonic crystal may include a first optical medium characterized by a first index of refraction, and an array of structures of a second optical medium situated within the first optical medium. In such implementations, the first optical medium is coupled to an optical gain medium and the second optical medium is characterized by a second index of refraction that is different from the first index of refraction. By way of example, and not by way of limitation, the array of structures of the second optical medium includes an array of holes formed in the first optical medium. In some such implementations, the photonic crystal cavity may be characterized by a six-fold symmetry and may be truncated in a hexagonal-shaped cavity. A radius of the holes may be tuned to a value for which a normalized quality factor difference between the fundamental mode and a next highest quality factor mode levels out at a constant value. In such a configuration, a threshold gain for the fundamental mode is smaller than a threshold gain of any other higher order mode.

A number of variations are possible on the basic VPUFC described above.

For example, in some implementations the one or more VCSEL may include an array of two or more VCSELs.

In some implementations the VPUFC may be characterized by a quality factor of 10,000 or greater, e.g., a quality factor between 10,000 and 30,000.

An output radiation of the VPUFC may be characterized by an operating linewidth of less than 1 kilohertz (kHz). As used, herein, “operating linewidth” refers to the linewidth actually measured in a real system. Operating linewidth is distinguished from intrinsic linewidth is what would be expected theoretically in the absence of environmental factors, such as temperature variation, vibration, noise in the pumping by the VCSELs, and variation in the device due to limits of manufacturing. For the purposes of the present disclosure it is useful to refer to a “normalized” linewidth, which may be defined as linewidth divided by operating frequency. The linewidth and operating frequency may be defined in terms of the optical frequency f of the output radiation of the VPUFC. In such cases, the normalized linewidth may be expressed as Δf/f, where Δf is the linewidth expressed in units of frequency. Alternatively, the linewidth and optical frequency may be expressed in terms of vacuum wavelength λ that corresponds to the optical frequency f and the relationship between the vacuum wavelength λ and optical frequency f and vacuum wavelength is c=λf. In such cases, the normalized linewidth may be expressed as Δλ/λ, where Δλ=λ(Δf/f). In some implementations, the operating frequency may range from f=800 Terahertz (THz) (λ=375 nm) to f=0.1 THz.(λ=3 mm) . The output radiation of the VPUFC may be characterized by a normalized linewidth between 10⁻⁷ and 10⁻³. By way of example, and not by way of limitation, the output radiation of the VPUFC may be characterized a vacuum wavelength of 2 microns, 1.55 microns, 1.3 microns or 0.9-1 microns.

According to aspects of the present disclosure the VPUFC may produce output radiation characterized by a power between 1 microwatt and 10 Watts, more preferably, between 10 milliwatts (mW) and 5 Watts (W).

According to aspects of the present disclosure the VPUFC may be characterized by an emission area having a characteristic dimension, e.g., length, width, or diameter, between 10 microns and 10 centimeters, more preferably between 100 microns and 5 millimeters.

Additional aspects of the present disclosure include a VCSEL-pumped uniform-field cavity (VPUFC) system with a VPUFC having a substrate, one or more VCSEL disposed on the substrate, a heat sink wafer disposed proximate an emitting surface of the VCSEL(s) so that the one or more VCSEL is disposed between the substrate and the heat sink wafer. A UFC is optically coupled to the VCSEL(s) through the heat sink wafer with the heat sink wafer disposed between the one or more VCSEL and the uniform field cavity. The VCSEL is configured to optically pump the UFC. One or more optical components are configured to receive an optical output of the VPUFC.

In such a system, the one or more optical components may include a lens configured to couple an optical output of the UFC to an optical fiber. In some such implementations the UFC may include a photonic crystal that includes an optical gain medium characterized by a first index of refraction, and an array of structures of a second optical medium situated within the optical gain medium. The second optical medium is characterized by a second index of refraction that is different from the first index of refraction. The photonic crystal may be characterized by a rhombic shape. The lens may be an axially asymmetric lens with a shorter focal length along one dimension.

In some implementations of the above-described system, the one or more optical components may include a beam steering element.

In some implementations of the above-described system, the one or more VCSEL includes an array of two or more VCSELs. In some versions of such implementations, the two or more VCSELs may be electrically injected and used to pump a photonic crystal cavity. The photonic crystal cavity may be configured to convert multimode output from the two or more VCSELs into a single coherent beam. The one or more optical components include a fiber attachment with a lens configured to couple an optical output of the UFC to an optical fiber. The compact design of the VPUFC in such implementations allows it to have a volume of less than 1 cm³.

According to aspects of the present disclosure a method for manufacturing a VCSEL-pumped uniform-field cavity (VPUFC) may proceed as follows. One or more vertical cavity surface emitting laser (VCSEL) may be bonded to a substrate. A heat sink wafer may be disposed proximate an emitting surface of the VCSEL, whereby the one or more VCSEL is disposed between the substrate and the heat sink wafer. A uniform field cavity (UFC) may be optically coupled to the one or more VCSEL through the heat sink wafer, wherein the heat sink wafer is disposed between the one or more VCSEL and the uniform field cavity, wherein the one or more VCSEL is configured to optically pump the UFC.

In some implementations of the above method, optically coupling a uniform field cavity (UFC) to the one or more VCSEL through the heat sink wafer may include forming a photonic crystal from an optical gain medium and disposing the heat sink wafer between the optical gain medium and the one or more VCSEL. The photonic crystal may be formed from the optical gain medium, e.g., by forming an array of holes in the optical gain medium. Forming the array of holes in the optical gain medium may include forming one or more holes in the optical gain medium by a lithography and etch process that produces high-verticality, smooth-sidewall etch holes. By way of example, and not by way of limitation, the lithography and etch process includes a photolithography, electron beam lithography, or imprint lithography process to define the array of holes in the optical gain medium. The lithography and etch process may include a dry etch process to form the array of holes at locations defined by the photolithography, electron beam lithography, or imprint lithography process. The dry etch process may include, e.g., reactive ion etching (RIE), or inductively coupled plasma (ICP) etching.

### BRIEF DESCRIPTION OF THE DRAWINGS

FIG. 1A is a scanning electron micrograph illustrating the design and principle of a proposed laser cavity according to aspects of the present disclosure.

FIG. 1B illustrates plots of electric field intensity and phase the aperture of the proposed laser cavity of FIG. 1A.

FIG. 2A is a graph depicting normalized Q-factor difference or threshold gain ratio for field cavities.

FIG. 2B is a scanning electron micrograph illustrating a 44-micron hexagonal field cavity having an array of holes.

FIG. 2C is a graph illustrating multimode emission for a field cavity of the type shown in FIG. 2B.

FIG. 2D is a graph illustrating single mode emission for a field cavity of the type shown in FIG. 2B.

FIG. 2E is a scanning electron micrograph illustrating a 64-micron hexagonal field cavity having an array of holes.

FIG. 2F is a graph illustrating multimode emission for a field cavity of the type shown in FIG. 2E.

FIG. 2G is a graph illustrating single mode emission for a field cavity of the type shown in FIG. 2E.

FIG. 3A is a graph depicting scaling of beam divergence angle as a function of cavity size for a field cavity according aspects of the present disclosure.

FIG. 3B is a scanning electron microscope image of a field cavity with a diameter of 44 am.

FIG. 3B is a scanning electron microscope image of a field cavity with a diameter of 44-μm.

FIG. 3D is a Fourier image illustrating the far field bean profile for the field cavity of FIG. 3B.

FIG. 3E is a Fourier image illustrating the far field bean profile for the field cavity of FIG. 3C.

FIG. 4 illustrates an example of a proposed VCSEL-pumped uniform-field cavity (VPUFC) according to aspects of the present disclosure.

FIG. 5A illustrates a plan view of a photonic crystal cavity having a hexagonal configuration according to an aspect of the present disclosure.

FIG. 5B illustrates a plan view of a photonic crystal cavity having a rhomboidal configuration according to an aspect of the present disclosure.

FIG. 5C is a Fourier image illustrating the far field bean profile for the field cavity of FIG. 5A.

FIG. 5D is a Fourier image illustrating the far field bean profile for the field cavity of FIG. 5B.

FIG. 6 is a cross-sectional diagram depicting a VPUFC according to aspects of the present disclosure.

### DETAILED DESCRIPTION

Semiconductor lasers are approaching their limits in scalability. Conventional semiconductor lasers, while compact and efficient, are prone to multimode operation at increased power outputs. This generally restricts their usage to low power, low-cost commercial applications. A novel laser cavity according to aspects of the present disclosure enables semiconductor lasers to maintain single-mode operation regardless of increase in cavity size. This allows high-power emission from relatively compact lasers, without sacrificing key performance parameters such as beam quality, spectral purity, and efficiency. Aspects of the present disclosure leverage a design framework based on photonic crystals to deliver high-intensity, coherent light, enabling semiconductor lasers to branch into a variety of industries.

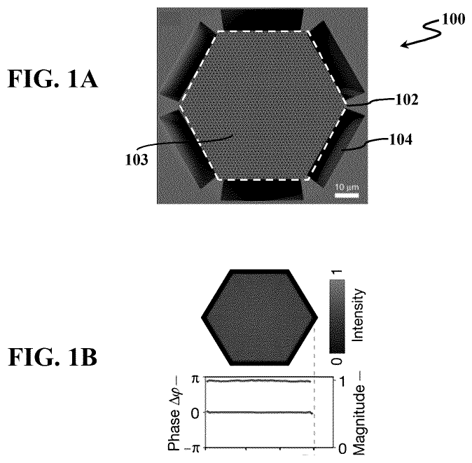

A scanning electron microscope image of a prototype device is shown in FIG. 1A. The photonic crystal has a six-fold symmetry and is truncated in a hexagonal-shaped cavity which also forms the emission aperture of the laser. A key feature of this cavity is that it supports a uniform field distribution across the entire gain region. This eliminates spectral-hole burning and prevents higher-order modes from participating in the lasing process. The uniformity of the electric field intensity across the cavity is shown in FIG. 1B and is maintained no matter the size of the cavity. We will refer to such a cavity as a uniform-field cavity (UFC) in this disclosure.

The scanning electron microscope image in FIG. 1A depicts an example of a photonic crystal cavity 100. The cavity 100 includes an array of structures 103 formed in a first optical medium 102 characterized by an index of refraction. The array of structures 103 is made of a second optical medium having a different index of refraction than the first optical medium 102. In the example depicted in FIG. 1A, the array of structures 103 is an array of holes formed in the first optical medium 102. The edges of the cavity 102 are parallel to the lattice vectors of the array of structures 103. In the illustrated implementation the photonic crystal has a six-fold symmetry and is truncated as a hexagon by cavity structures 104. In alternative implementations, the cavity may be truncated as a rhombus, or any arbitrary cavity shape with the cavity edges parallel to the lattice vectors. A radius of the holes 103 may be tuned to a value for which a normalized quality factor difference between a fundamental mode and a next highest quality factor mode levels out at a constant value. As a result, a threshold gain for the fundamental mode is smaller than a threshold gain of any other higher order mode. The electric field intensity plot depicted in FIG. 1B shows uniform distribution of field intensity and uniform phase Δφ across the aperture of the cavity 100. In some implementations, the first optical medium 102 may be coupled to an optical gain medium (not shown), wherein the second optical medium is characterized by a second index of refraction that is different from the first index of refraction.

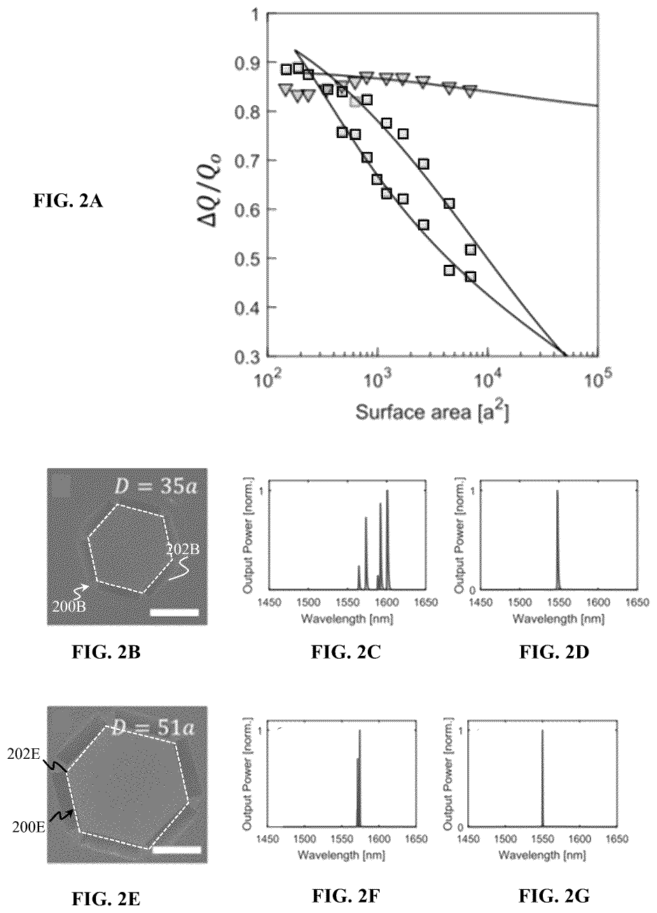

Further computational evidence of the single-mode operation can be found by comparing the quality factor or the threshold gain of the cavity modes. In conventional cavities, the quality factor of the higher order mode approaches the quality factor of the fundamental mode as seen from the plots denoted by the squares in FIG. 2A. This makes the laser susceptible to multimode emission. However, when the radius of holes 103 is tuned to the correct value, the normalized quality factor difference between the fundamental mode and the next highest quality factor mode levels out at a constant value of 0.8, as indicated by the plot denoted by the triangles. This means that the threshold gain for the fundamental mode will always be smaller than the threshold gain of any other higher order mode. Once the lasing of the fundamental mode begins, the uniform field distribution will prevent higher order modes from participating even as the power pumped into the cavity increases.

The scanning electron microscope image and the lasing spectra of two devices with different sizes and hole radii are shown in FIG. 2 b-g. FIG. 2B is a scanning electron micrograph of a cavity 200A of 44-micron diameter D having an array of structures 202B. In FIG. 2B, the annotation D=35a indicates that the diameter D of the cavity is 35 times the periodicity a of the array of structures. In this example, the structures in the array 202B are holes of roughly circular cross-section. For this device, when the holes in the array 202B are not manufactured at the desired radius, the devices is prone to multimode emission as indicated by the plot of output power versus wavelength depicted in FIG. 2C. However, devices of the type shown in FIG. 2B manufactured with holes of the correct radius maintain single-mode operation, as indicated by the plot of output power versus wavelength depicted in FIG. 2D. This behavior continues as the diameter of the cavity increases. For example, FIG. 2E is a scanning electron micrograph of a hexagonal cavity 200E of 64-micron diameter D having an array of structures 202E. The annotation D=51a in FIG. 2E indicates that the diameter D of the cavity is 51 times the periodicity a of the array 202E. The structures in the array 202E are holes of roughly circular cross-section. If the holes in the array 202E are not manufactured at the desired radius, the device is prone to multimode emission as indicated by the plot of output power versus wavelength depicted in FIG. 2F. However, devices of the type shown in FIG. 2E with holes of the correct radius maintain single-mode operation, as indicated by the plot of output power versus wavelength depicted in FIG. 2G.

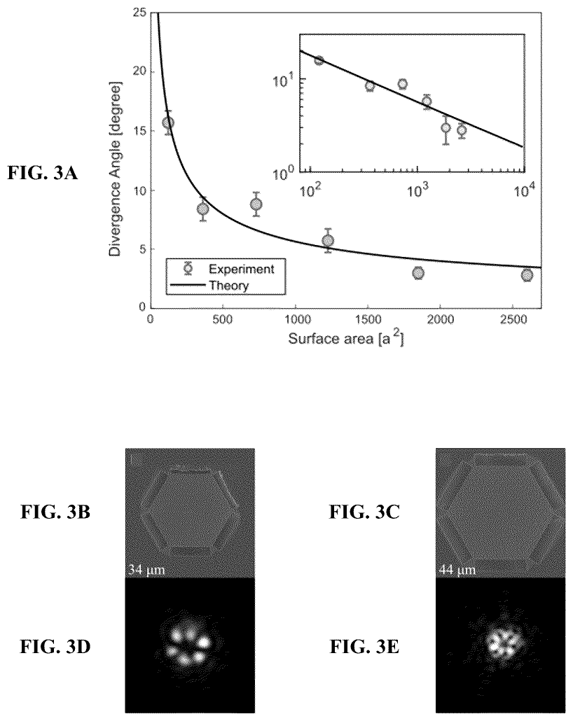

The divergence of the beam emitted by a cavity decreases with the size of the cavity - therefore, further evidence of the uniform field distribution can be found in the scaling of the divergence angle. Diffraction from a uniformly illuminated cavity scales inversely with the diameter of the cavity as seen in FIG. 3A. The far field profile of the beam can be visualized by a Fourier imaging setup. The hexagonal shape of the 34-μm and 44-μm diameter cavities shown in FIG. 3B and FIG. 3C, respectively, is reflected in the six lobes of the corresponding far field beam profiles of the laser beams shown in the Fourier images depicted in FIG. 3D and FIG. 3E, respectively. The reduction in divergence angle with increasing cavity diameter may be clearly seen by comparing the lobes in FIG. 3D to the lobes in FIG. 3E.

Thus, as may be seen from the foregoing, aspects of the present disclosure allow for a photonic crystal cavity that is scale-invariant and capable of emitting coherent beams of light with high beam quality.

### Identification and Significance of the Problem or Opportunity

Surveillance and reconnaissance are core defense necessities during both peacetime and warfare, critical for gathering intelligence on emerging threats or monitoring hostile positions. One of the key logistical challenges the military faces is the efficient and effective surveillance of large areas—across land, sea, air, and space—using compact, reliable, and high-resolution sensing devices. Current long-range detection systems, such as conventional LIDAR, are bulky, power-hungry, and difficult to maintain, while alternatives like radar often lack the resolution needed for precise monitoring. These limitations create an urgent need for more compact, high-performance solutions.

Semiconductor lasers present a promising solution due to their low mass, compact form factor, and ability to integrate directly with electronic systems. However, their utility in real-world applications remains constrained by challenges with power output and beam quality, particularly in the 2-micron wavelength range. This wavelength regime is critical for defense and other free-space applications due to several key advantages: it is eye-safe, overlaps with an atmospheric transmission window, and is absorbed by important gases such as CO₂, O₃, CH₄, and water vapor. Eye safety is essential in defense applications to reduce the risk of accidental damage from stray reflections, making 2-micron lasers ideal for deployment on ships, drones, and aircraft operating near friendly personnel.

The 2-micron wavelength also offers a higher propagation range compared to shorter wavelengths, reducing overall power requirements and enabling applications such as long-range ground-to-air/space communication. This reduces reliance on radio systems, which are vulnerable to interference, providing a more secure and reliable communication channel for troops in remote locations. Additionally, this wavelength is highly relevant for atmospheric sensing, allowing for the monitoring of environmental factors such as cloud cover, wind turbulence, and harmful gases, enhancing both environmental and defense-related surveillance capabilities.

Commercial uses of 2-micron lasers extend well beyond defense. The high absorption by water, a major component of biological tissue, makes this wavelength highly suited for medical applications, particularly in laser-based surgeries. At this wavelength, lasers can precisely heat and ablate small areas of tissue, enabling highly accurate surgical procedures with minimal damage to surrounding healthy tissue. This opens the door for advancements in minimally invasive surgeries, such as those required in delicate fields like ophthalmology and dermatology, where precision is critical. Furthermore, 2-micron lasers have potential in industrial processing of materials sensitive to thermal damage, offering precise cutting, welding, or engraving in sectors like microelectronics and biotechnology.

In addition to the immediate advantages at 2 microns, the innovations targeted in this proposal will serve as a springboard for broader wavelength applications. The core semiconductor laser technology being developed that is based on photonic crystal surface-emitting laser (PCSEL) architecture, offers scalability to other wavelengths, particularly in the near-and mid-infrared regions. This flexibility will benefit a wide array of future applications—ranging from telecommunications to environmental monitoring—at different wavelengths. For instance, shorter vacuum wavelengths in the near-infrared (such as 1.55 microns) are vital in fiber-optic communication systems, while longer wavelengths in the mid-infrared (up to 10 microns) are key in gas sensing, pollution monitoring, and security imaging systems. Other vacuum wavelengths of interest include, but are not limited to, 1.55 microns, 1.3 microns or 0.9-1 microns.

Thus, while portions of the present disclosure focus on 2-micron lasers, the technological advancements and scaling techniques developed here have the potential to revolutionize laser performance across a much broader spectrum, impacting a wide range of industries from medical technology to communications, energy, and manufacturing. As such, aspects of the present disclosure are not limited to implementations involving 2-micron lasers.

### Technical Objectives

According to aspects of the present disclosure, VPUFCs and optical systems that incorporate them may accomplish the following technical objectives: 1) Laser emission at 2000-2100 nm, 2) Power output >500 mW with good beam quality (M2<1.2) for efficient fiber coupling, 3) Compact (<10,000 cm3) and lightweight (<1 kg) device operating at room temperature, 4) Narrow intrinsic linewidth (<1 kHz), and 5) Control over output power, polarization, and spectral width.

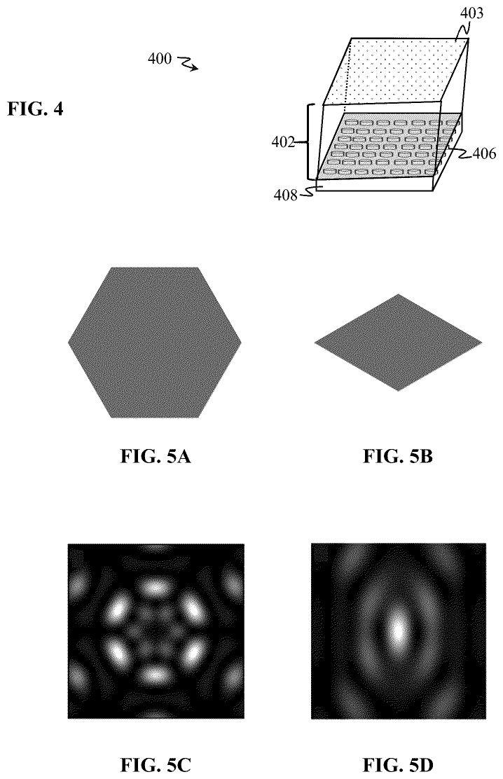

This Section describes how VCSEL-pumped Uniform-Field Cavities (VPUFCs), such as the one rendered in FIG. 4, can achieve each of these objectives. The applications unlocked by fulfilling these metrics are also briefly summarized. FIG. 4 depicts a three-dimensional rendering of an implementation of a VPUFC 400 according to certain aspects of the present disclosure. An array of electrically activated VCSELs 406 mounted to a substrate 408 pumps a single uniform field cavity 402, exciting a uniform mode with narrow divergence, as described above. The uniform field cavity includes an array of structures 403, e.g., holes, which may be configured as described above. A separately attached microlens (not shown) may then focus the uniform mode to couple it into an optical fiber.

As discussed hereinabove, the far field profile of the beam from VPUFCs according to aspects of the present disclosure can be visualized by a Fourier imaging. FIGS. 5A-5B illustrate far field control for field cavities of different shapes. In FIG. 5A, the photonic crystal cavity is hexagonal in shape and in FIG. 5B the shape is rhomboidal. FIG. 5C and FIG. 5D depict the corresponding far field beam profiles for the cavities shown in FIG. 5A and FIG. 5B, respectively. The rhombic cavity shown in FIG. 5C can be efficiently coupled to a single-mode fiber due to a Gaussian beam profile depicted in FIG. 5D.

### Objective 1: Laser Emission at 2000-2100 nm

The emission wavelength of VPUFCs according to aspects of the present disclosure is governed both by the choice of gain material and the geometric configuration of the photonic crystal unit cell in the uniform field cavity 402. This approach is wavelength-agnostic, as long as the refractive index contrast between the gain material and cladding ensures sufficient optical confinement. While efforts may be focused on 1550 nm for telecommunications applications, the underlying physical principles remain unchanged for longer wavelengths. Various semiconductor materials, such as Ingas', InP, and GaSb, can be tailored to provide gain at 2000 nm.

Achieving laser emission at this wavelength unlocks significant dual-use applications. In defense, compact 2-micron lasers will enable safer, long-range LADAR and communication systems for airborne or satellite-based platforms. Commercially, they can enhance atmospheric sensing systems, including greenhouse gas monitoring, weather prediction, and air quality measurement. Additionally, this emission range overlaps with bioimaging and medical applications, enabling more precise surgeries or diagnostic tools without harming surrounding tissues, due to the eye-safe and tissue-absorbing properties of the 2-micron spectrum.

### Objective 2: Power Output>500 mW with Good Beam Quality (M²<1.2) for Efficient Fiber Coupling

Since the laser cavity used in VPUFCs according to aspects of the present disclosure support a uniform fundamental mode, the output power can be controlled by simply changing the size of the cavity. Based on the experimental results, the inventors estimate a cavity size of ˜3 mm can emit around 1 W of single-mode power. The divergence angle of the beam is governed by the cavity size, as per the Fourier relation, causing larger cavities to emit narrower beams with a smaller M², as shown by FIG. 3A). It is estimated that a cavity size of 3 mm will emit a beam with a half-angle divergence of <0.05 degrees (<1 milliradian (mrad)).

Along with the divergence, the shape of the beam is also important for fiber coupling. To couple light into a single-mode polarization maintaining fiber, the laser beam should have a large overlap integral with the Gaussian mode profile of the fiber. The beam emitted by a hexagonal cavity (e.g., as depicted in FIG. 5A and FIG. 5C) that was demonstrated is unsuitable for this purpose. However, because the uniform field profile strongly interacts with the boundaries of the cavity, changing its shape can have significant consequences on the emitted beam. For example, the rhombic cavity shown in FIG. 5B, emits a Gaussian, but rotationally asymmetric beam. Such a profile will have a much larger overlap with the fiber waveguide mode, and this can be further enhanced by using a single axially asymmetric lens with a shorter focal length along one dimension. Laser light coupled into a fiber adds significant versatility, allowing the laser system to be adapted for a wide range of military and commercial applications. Some notable use cases, among others, are discussed below.

Power Scaling through Fiber Amplifiers: Fiber-coupled laser systems may be easily amplified using doped fibers (e.g., erbium-or ytterbium-doped fibers), increasing output power by orders of magnitude without compromising beam quality. This is particularly useful in high-power laser systems for directed energy applications, where compact size and high output are critical.

Long-distance Free-space Communications: When coupled to a fiber, the laser may interface with beam-steering mechanisms that allow precise pointing in free-space communication applications, including satellite-to-ground or drone-to-ground communications.

Photonic Integrated Circuits (PICs): Fiber-coupled lasers may seed light into photonic integrated circuits, which are essential for high-speed optical communication systems, signal processing, and optical computing. PICs are increasingly relevant in both commercial telecom networks and military communication systems, offering fast and secure data transmission with reduced power consumption. Increased high-power non-linear interactions can be used to generate new frequencies or enable quantum communication protocols.

Sensing and Imaging Applications: The uniform beam quality (M²<1.2) ensures high precision and focus in imaging systems, making the laser suitable for LIDAR applications, hyperspectral imaging, and terrain mapping. When deployed from airborne platforms, such as drones, the laser can enable high-resolution detection and identification of targets over vast areas.

### Objective 3: Compact (<10,000 cm3) and Lightweight (<1 kg) Device Operating at Room Temperature

Approach: A key advantage of semiconductor lasers is their small form factor and large power density. However, compact semiconductor lasers such as VCSELs and edge-emitting lasers suffer from low power output and/or poor beam quality. PCSELs are a promising technology that can emit high brightness light with good beam quality, but conventional strategies for PCSEL design struggle to maintain their performance at longer wavelengths. As a result, we propose a VCSEL-pumped Uniform-Field Cavity (VPUFC) laser. A VCSEL array will be electrically injected and used to pump a photonic crystal cavity, which will convert the low beam quality, multimode output from the VCSELs into a single coherent beam. Both the pump and emitters will be fabricated at wafer-scale, providing a path towards low-cost mass manufacturing. The fully co-packaged device, consisting of the lower volume laser chip (<1 cm³), medium volume fiber attachment (<50 cm³) and the higher volume thermal management (<100 cm³), will weigh less than 0.25 kg.

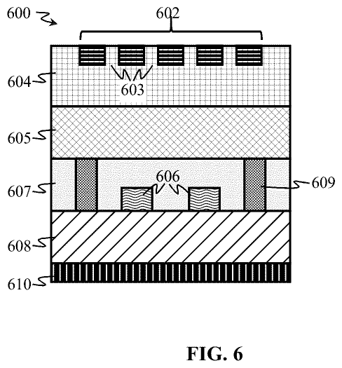

High power density semiconductor lasers struggle with heat dissipation generated in a mm-scale, nm-thick region. Conventionally, multi-Watt PCSELs rely on active water cooling that further increases the size and weight of the package. A key advantage of the uniform field distribution in VPUFCs according to aspects of the present disclosure is that heat also remains uniformly spread out across the aperture rather than creating a hotspot in the center for the traditional sinusoidal mode laser cavities. We can achieve power scaling by simply increasing the size of the cavity without increasing the heat density in the center. To enable high heat dissipation, we plan to integrate multiple passive heat sinks attached to the laser die. We will also use a thermally conductive substrate, such as Diamond or Silicon, bonded to the photonic crystal cavity. In addition, we can engineer deep etched heat sinks in silicon to improve its moderate thermal conductivity while reducing per-unit cost as compared to Diamond. These passive heat structures can also be coupled with air cooling when operating in the few Watts range to allow for room temperature operation of our device. A cross-sectional schematic is seen below in FIG. 6.

FIG. 6: A cross-sectional diagram of a proposed implementation of a VPUFC 600. An array of VCSELs 606 is bonded to a photonic crystal Uniform Field Cavity 602. The VCSEL array 606 may be embedded in a structural epoxy 607 and mounted to a VCSEL substrate 608. The uniform field cavity includes an array of structures 603, e.g., holes, which may be configured as described above. The uniform field cavity 602 may be embedded in a transparent cladding, e.g., made of silicon dioxide. In the implementation depicted in FIG. 6, multiple heat sinks may be used to stimulate heat dissipation, enabling consistent room temperature operation. For example, the uniform-field cavity 602 may be bonded to the VCSEL array 606 via a transparent heat sink wafer 605 and one or more eutectic bonds 609 formed through openings in the structural epoxy 607. A metallic heat sink 610 may be bonded to a back side of the VCSEL substrate 608.

Applications: The development of a compact and lightweight 2-micron laser system is crucial for many modern defense and commercial applications where portability and space constraints are critical factors. Achieving room temperature operation without the need for bulky active cooling systems is an additional advantage that keeps the device footprint low. Some key applications include those discussed below.

Unmanned Aerial Vehicles (UAVs) and Drones: The compact size and lightweight nature of the laser make it ideal for integration into UAVs and drones for surveillance, reconnaissance, and target identification. The reduced SWaP (size, weight, and power) footprint allows for longer flight times, increased payload capacity, and improved mobility in military as well as civilian operations such as wildfire mitigation.

Satellite and Space-based Systems: Compact laser systems are highly desirable for USSF and commercial space applications where every gram of weight and cubic centimeter of volume is valuable. Lightweight 2-micron lasers can be used in satellite-based LIDAR systems for atmospheric monitoring, remote sensing, or even laser-based communication between satellites and ground stations. The reduced thermal management requirements also benefit space systems by minimizing heat dissipation in vacuum environments.

Wearable and Portable Sensing Systems: For military personnel or field operatives, wearable devices or handheld systems incorporating compact laser technologies can provide real-time situational awareness, such as detecting chemical or biological threats. The low weight and volume enable portability without sacrificing performance, ensuring that personnel in the field can carry advanced sensing systems without adding a significant burden.

Medical and Industrial Equipment: The small size and high power density of this laser makes it an attractive option for portable or mobile medical devices, such as laser-based surgery tools, where precision, compactness, and efficiency are vital. Similarly, in industrial settings, compact laser systems can be integrated into handheld or mobile platforms for tasks like precision cutting, welding, and material processing, where space and weight constraints are a concern.

Laser-based Communication Systems: Compact fiber-coupled lasers can be deployed in mobile platforms, such as ground vehicles or ships, for secure, long-range, and interference-resistant optical communication links. The lightweight and small form factor of the proposed system enables flexibility in deployment in various environments.

### Objective 4: Narrow Intrinsic Linewidth (<1 kHz)

Approach: The intrinsic linewidth of a laser is primarily determined by the photon loss rate (inversely related to the cavity quality factor) and the output power of the laser, as governed by the Schawlow-Townes relationship. According to aspects of the present disclosure, it is believed to be possible to achieve an intrinsic linewidth of less than 1 kHz by optimizing the quality factor of the laser cavity and maximizing output power while minimizing phase-noise contributions.

During initial efforts, the inventors demonstrated quality factors exceeding 10,000 for cavities with diameters of ˜100 μm. Scaling the cavity to over 1 mm is expected to produce an even higher quality factor, with conservative estimates predicting a value of at least 30,000. The Schawlow-Townes equation predicts the linewidth will decrease proportionally with increased quality factor and output power. Assuming a power output of 500 mW and a linewidth enhancement factor of 4 (common for semiconductor lasers), this yields an estimated linewidth of 999 Hz. In practice, a much larger quality factor is expected, reducing intrinsic linewidth to well below the sub-kHz range.

Some potential applications of lasers with narrow intrinsic linewidths are discussed below.

Telecommunications: Narrow linewidth lasers enable high-density data transmission through dense wavelength-division multiplexing (DWDM). By maintaining sub-kHz linewidths, these lasers allow for tightly spaced optical channels, maximizing bandwidth and minimizing crosstalk. This is particularly valuable for long-haul fiber-optic communications and next-generation 5G networks.

Quantum and atomic technologies: Narrow linewidth is essential for stabilizing atomic transitions and controlling quantum states. In atomic clocks and quantum computing, for example, lasers with sub-kHz linewidths ensure precise control over qubits, improving the accuracy and reliability of quantum operations. This can advance applications in secure communications, quantum sensing, and quantum metrology and enable the next generation of quantum devices and on-chip atomic clocks.

Precision sensing: In time-of-flight LIDAR systems, a narrow linewidth enhances range accuracy and signal-to-noise ratios, making these lasers indispensable for long-range sensing, environmental monitoring, and topographical mapping. By reducing signal noise, these lasers can offer higher-resolution data in atmospheric sensing applications, improving the detection of gases and particles in the air, such as pollutants and greenhouse gases.

### Objective 5: Control Over Output Power, Polarization, and Spectral Width

Approach: PCSELs naturally offer extensive control over key emission properties, and VPUFC designs according to aspects of the present disclosure enhance this flexibility by introducing multiple degrees of freedom. These include cavity size and shape, unit cell geometry and symmetry, substrate refractive index, and pump power density. Each of these parameters can be tuned to control the output power, polarization, and spectral width of the laser.

Output Power: The output power can be adjusted in two primary ways. First, by increasing the size of the photonic crystal cavity, we can scale up the power without significantly altering the emission characteristics, as described in earlier objectives. The uniform field profile ensures that larger cavities emit higher power while maintaining beam quality. Second, dynamic control of output power is achievable by adjusting the pump energy supplied to the VCSEL array. This offers real-time tunability, though enhanced heat management may be required for higher power levels. In future iterations of the VPUFC design, optimized heat dissipation methods, such as improved thermal sinking, may be utilized to support sustained high-power operation.

Spectral Width: The spectral width can be manipulated through careful tuning of the cavity design, particularly the size of the cavity and the refractive index contrast between the gain material and the cladding—both of which affect the quality factor. Minimal modifications to the cavity structure can potentially lead to significant control over the emitted spectral width, allowing the laser to be fine-tuned for specific applications that require either narrowband or broader emission profiles.

Polarization Control: The VPUFC design offers unparalleled control over the beam's polarization properties. Due to the rotational asymmetry of the proposed rhombic cavity, we easily emit x- and y-direction linear polarizations by simply rotating the cavity by 90 degrees. By altering the symmetry of the photonic crystal unit cells or modifying the cavity boundaries, we can more complex polarization states, including linearly or circularly polarized light. Notably, this design enables the generation of beams with orbital angular momentum (OAM), characterized by vortices in the electric field distribution.

Applications: Controlling output power, polarization, and spectral width enables advanced optical communication systems, particularly in multiplexing for increased bandwidth efficiency. Polarization control, especially with OAM beams, opens the door to spatial division multiplexing, drastically increasing data capacity in free-space and satellite communications as well as biological and atomic trapping.

Although certain objectives and potential applications of VPUFC and corresponding optical systems are described herein, those skilled in the art will appreciate that other objectives may accomplished and other potential applications may be developed that are consistent with these teachings. Furthermore, although certain configurations of VPUFC and optical systems that incorporate them are described herein, those skilled in the art will be able to device other VPUFC configurations and optical systems that are consistent with these teachings.

While the above includes a complete description of the preferred embodiment of the present invention, it is possible to use various alternatives, modifications, and equivalents. Therefore, the scope of the present invention should be determined not with reference to the above description but should, instead, be determined with reference to the appended claims, along with their full scope of equivalents. Any feature described herein, whether preferred or not, may be combined with any other feature described herein, whether preferred or not. In the claims that follow, the indefinite article “A,” or “An” refers to a quantity of one or more of the item following the article, except where expressly stated otherwise. The appended claims are not to be interpreted as including means-plus-function limitations, unless such a limitation is explicitly recited in a given claim using the phrase “means for.”

1. A VCSEL-pumped uniform-field cavity (VPUFC), comprising:
a substrate;
one or more vertical cavity surface emitting laser (VCSEL) bonded to the substrate;
a heat sink wafer disposed proximate an emitting surface of the VCSEL, whereby the one or more VCSEL is disposed between the substrate and the heat sink wafer;
a uniform field cavity (UFC) optically coupled to the one or more VCSEL through the heat sink wafer, wherein the heat sink wafer is disposed between the one or more VCSEL and the uniform field cavity, wherein the one or more VCSEL is configured to optically pump the UFC.

2. The VPUFC of claim 1, wherein the uniform field cavity is configured to support a fundamental mode of radiation.

3. The VPUFC of claim 2, wherein the uniform field cavity includes photonic crystal cavity.

4. The VPUFC of claim 3, wherein the photonic crystal has a six-fold symmetry and is truncated as a hexagon, rhombus, or any arbitrary cavity shape with the cavity edges parallel to the lattice vectors.

5. The VPUFC of claim 3, wherein the photonic crystal includes a first optical medium characterized by a first index of refraction, and an array of structures of a second optical medium situated within the first optical medium, wherein the first optical medium is coupled to an optical gain medium, wherein the second optical medium is characterized by a second index of refraction that is different from the first index of refraction.

6. The VPUFC of claim 5, wherein the array of structures of the second optical medium includes an array of holes formed in the first optical medium.

7. The VPUFC of claim 6, wherein a radius of holes is tuned to a value for which a normalized quality factor difference between the fundamental mode and a next highest quality factor mode levels out at a constant value, whereby a threshold gain for the fundamental mode is smaller than a threshold gain of any other higher order mode.

8. The VPUFC of claim 1, wherein the one or more VCSEL includes an array of two or more VCSELs.

9. The VPUFC of claim 1, wherein the VPUFC is characterized by a quality factor of 10,000 or greater.

10. The VPUFC of claim 1, wherein an output radiation of the VPUFC is characterized by an operating linewidth of less than 1 kilohertz (kHz).

11. The VPUFC of claim 1, wherein an output radiation of the VPUFC is characterized by an operating frequency between 0.1 terahertz and 800 terahertz.

12. The VPUFC of claim 1, wherein an output radiation of the VPUFC is characterized by a normalized linewidth between 10⁻⁷ and 10⁻³.

13. The VPUFC of claim 1, wherein an output radiation of the VPUFC is characterized by a power between 1 microwatt and 10 Watts.

14. The VPUFC of claim 1, wherein the UFC is characterized by an emission area having a characteristic dimension between 10 microns and 10 centimeters.

15. A VCSEL-pumped uniform-field cavity (VPUFC) system, comprising:
a VPUFC having a substrate, one or more vertical cavity surface emitting laser (VCSEL) disposed on the substrate, a heat sink wafer disposed proximate an emitting surface of the VCSEL, whereby the one or more VCSEL is disposed between the substrate and the heat sink wafer;
a uniform field cavity (UFC) optically coupled to the one or more VCSEL through the heat sink wafer, wherein the heat sink wafer is disposed between the one or more VCSEL and the uniform field cavity, wherein the one or more VCEL is configured to optically pump the UFC; and
one or more optical components configured to receive an optical output of the VPUFC.

16. The system of claim 15, wherein the one or more optical components include a lens configured to couple an optical output of the UFC to an optical fiber.

17. The system of claim 16, wherein the UFC includes a photonic crystal, wherein the photonic crystal includes an optical medium characterized by a first index of refraction, and an array of structures of a second optical medium situated within the optical gain medium, wherein the second optical medium is characterized by a second index of refraction that is different from the first index of refraction.

18. The system of claim 17, wherein the photonic crystal is characterized by a rhombic shape.

19. The system of claim 18, wherein the lens is an axially asymmetric lens with a shorter focal length along one dimension.

20. The system of claim 15, wherein the one or more optical components include a beam steering element.

21. The system of claim 15, wherein the one or more VCSEL includes an array of two or more VCSELs.

22. The system of claim 21, wherein the two or more VCSELs are electrically injected and used to pump a photonic crystal cavity.

23. The system of claim 22, wherein the photonic crystal cavity is configured to convert multimode output from the two or more VCSELs into a single coherent beam.

24. The system of claim 23, wherein the one or more optical components include a fiber attachment with a lens configured to couple an optical output of the UFC to an optical fiber.

25. The system of claim 24, wherein the VPUFC has a volume of less than 1 cm³.

26. A method for manufacturing a VCSEL-pumped uniform-field cavity (VPUFC), comprising:
bonding one or more vertical cavity surface emitting laser (VCSEL) bonded to a substrate;
disposing a heat sink wafer proximate an emitting surface of the VCSEL, whereby the one or more VCSEL is disposed between the substrate and the heat sink wafer;
optically coupling a uniform field cavity (UFC) to the one or more VCSEL through the heat sink wafer, wherein the heat sink wafer is disposed between the one or more VCSEL and the uniform field cavity, wherein the one or more VCEL is configured to optically pump the UFC.

27. The method of claim 26, wherein optically coupling a uniform field cavity (UFC) to the one or more VCSEL through the heat sink wafer includes forming a photonic crystal from an optical gain medium and disposing the heat sink wafer between the optical gain medium and the one or more VCSEL.

28. The method of claim 27, wherein forming the photonic crystal from the gain medium includes forming an array of holes in the optical gain medium.

29. The method of claim 28, wherein forming the array of holes in the optical gain medium includes forming one or more holes in the optical gain medium by a lithography and etch process that produces high-verticality, smooth-sidewall etch holes.

30. The method of claim 29, wherein the lithography and etch process includes a photolithography, electron beam lithography, or imprint lithography process to define the array of holes in the optical gain medium.

31. The method of claim 30, wherein the lithography and etch process includes a dry etch process to form the array of holes at locations defined by the photolithography, electron beam lithography, or imprint lithography process.

32. The method of claim 31, wherein the dry etch process include reactive ion etching (RIE), or inductively coupled plasma (ICP) etching.
